(19) United States
(12) Patent Application Publication
(10) Pub. No.: US 2025/0120036 A1
(43) Pub. Date: Apr. 10, 2025

(54) RACKSIDE AUTOMATION FOR DATACENTER OPTIMIZATION

(71) Applicant: Intel Corporation, Santa Clara, CA (US)

(72) Inventors: Ralph Jensen, Tumwater, WA (US); Michael Crocker, Portland, OR (US); Carl Williams, Manitou Springs, CO (US)

(73) Assignee: Intel Corporation, Santa Clara, CA (US)

(21) Appl. No.: 18/983,630

(22) Filed: Dec. 17, 2024

(51) Int. Cl. H05K 7/14

(52) U.S. Cl. CPC H05K 7/1488; H05K 7/1497

(57) ABSTRACT

A datacenter including a plurality of racks. The racks associated with a motorized and/or automated system to move the racks between first and second positions. In the first position, the racks are arranged in a side-by-side fashion in one or more rows. In the second position, a rack is moved so that a lateral side of the rack is accessible. In some embodiments, the racks include a motor and gear system for interacting with tracks. In some embodiments, each of the racks includes a plurality of chassis, each chassis including a plurality of input/output (I/O) connectors to receive a connector of a cable, the plurality of I/O connectors are arranged along a lateral side of the chassis so that they are accessible when the rack is in the second position. In use, the racks may be moved between the first and second positions while the chassis remain in normal operation.

### BACKGROUND

Advancements in networking have enabled the rise in pools of physical resources. A pool of physical resources may be formed from a physical infrastructure including disaggregate physical resources, such as, for example, compute and storage resources found in large datacenters. The physical infrastructure can include a number of computing systems having processors, memory, storage, networking, power, cooling, etc. Management entities of these datacenters can aggregate a selection of the physical resources to form servers and/or physical computing hosts. These hosts can subsequently be allocated to execute software system and host containers and/or applications.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 illustrates a perspective view of a datacenter in accordance with one or more features of the present disclosure, FIG. 1 illustrating racks arranged in a plurality of rows, individual racks shown in the first or rest position and in the second or access position.

FIG. 2 illustrates an alternate perspective view of a datacenter in accordance with one or more features of the present disclosure.

FIG. 3 illustrates a detailed, exploded perspective view of a first embodiment of a floor track and gear system (e.g., a motorized system) in accordance with one or more features of the present disclosure.

FIG. 4 illustrates a detailed, exploded perspective view of a second embodiment of a floor track and gear system (e.g., a motorized system) in accordance with one or more features of the present disclosure.

FIG. 5 is a detailed cross-sectional view of an anti-tipping structure in accordance with one or more features of the present disclosure.

FIGS. 6A and 6B illustrate various views of a chassis being inserted into a rack in accordance with one or more features of the present disclosure.

FIGS. 7A and 7B illustrate various views of a chassis inserted into a rack in accordance with one or more features of the present disclosure.

FIGS. 8A-8D illustrate various views of a chassis in accordance with one or more features of the present disclosure.

### DETAILED DESCRIPTION

Embodiments generally relate to a motorized and/or automated system for moving racks in a datacenter (e.g., a modular datacenter). In use, by providing a modular (e.g., a motorized and/or automated) datacenter, access to the side panels of a rack is enabled.

Datacenters may generally be composed of a large number of racks that can contain numerous types of hardware or configurable resources (e.g., processing units, memory, storage, accelerators, networking, fans/cooling modules, power units, etc.). The types of hardware or configurable resources deployed in datacenters may also be referred to as physical resources. It is to be appreciated, that the size and number of physical resources within a datacenter can be large, for example, on the order of hundreds of thousands of physical resources. Furthermore, these physical resources can be pooled to form virtual computing platforms for a large number and variety of computing tasks.

As noted, some of the physical resources can be compute resources (e.g., central processing units, or the like) or accelerator resources (e.g., application specific integrated circuits, field-programmable gate arrays, or the like). Furthermore, the physical resources include memory. Physical resources may include resources of multiple types, such as-for example-processors, co-processors, accelerators, field-programmable gate arrays (FPGAs), graphics processing units (GPUs), memory, interconnect components, and storage. The embodiments are not limited to these examples.

Generally speaking, a datacenter includes a plurality of racks, each rack including or housing computing equipment comprising a plurality of physical resources (e.g., compute resources such as, for example, a chassis containing a sled or circuit boards or the like) (collectively referred to herein as “chassis”) interconnected by a multitude of cables and input/output connectors (I/O connectors). In use, the chassis houses components such as central processing units (CPUs), memory, and other components.

Generally speaking, the racks are designed and installed into permanent locations in rows with numerous racks aligned, side-by-side, in rows separated by aisles. In use, these aisles are arranged as hot-aisles and cold-aisles. Given the weight of each rack, during an initial installation, a rack may be rolled into position with casters, which are then disengaged from the floor to prevent the racks from subsequent movement. In addition, overhead or raised cables are connected to each chassis contained within each rack. As a result, any subsequent movement of a rack post installation requires disconnecting the incoming power and cabling connectors (e.g., each chassis must be disconnected from any associated cabling before the rack can be moved). In addition, as previously mentioned, datacenters include alternating hot-aisles and cold-aisles between adjacent rows of racks. As will be readily appreciated by one of ordinary skill in the art, cold air is funneled into the cold-aisles where the cold air travels into each of the racks. For example, the cold air may travel into the front side of the racks across the chassis (e.g., front-to-back) and out of the rear side of the rack, where the now hot air is funneled out of the hot-aisle of the datacenter. Alternatively and/or in addition, the air may travel back-to-front across the chassis and through the racks. In either manner, air travels from the cold-aisles into each rack across the chassis and into the hot-aisle to provide thermal cooling of each chassis within each rack.

Conventional datacenters suffer from a number of disadvantages. For example, over time, rack mounted chassis have become deeper and deeper (e.g., as measured front to back in a rack) to accommodate larger processors, increased numbers of dual in-line memory modules (DIMMs), increased numbers of networking, power and storage devices, etc. Nevertheless, the depth of the racks have remained the same. Meanwhile the heights of the chassis is also restricted and thus are little changed. As a consequence, the front and rear sides of the chassis contain the least amount of surface area on the chassis. Nevertheless, the front and rear sides of the chassis contain all of the I/O connectors facilitating networking ingress and egress, thermal fluid flow egress, power input, and other device connections. This, in turn, has led to severe congestion along the front and/or rear sides of the racks (e.g., the number of cables running alongside, for example, the rear side and connecting to the I/O connectors of the chassis has become numerous). As a result, cable management has become a major concern. In addition, inadequate thermal management has led to lower performance (e.g., numerous cables running along the rear side of the racks prevents, or at least minimizes, cooling air flow that travels from the cold-aisle to the hot-aisle as the cables block the flow of cold air). This has led to significant increases in temperatures within the hot-aisles within datacenters and to the deterioration of performance of the physical resources due to decreased thermal management.

The present disclosure provides one or more features for overcoming these problems. For example, the present disclosure provides a system and method for motorizing and/or automating movement of one or more racks within a datacenter. In addition, and/or alternatively, the present disclosure provides one or more features for reconfiguring one or more physical resources (e.g., computing equipment) within a rack. That is, the present disclosure provides a system or means of motorizing and/or automating movement of one or more of the plurality of racks within a datacenter thereby providing access to the lateral sides of a rack while in normal operation (e.g., the rack can be moved from a first or rest position to a second or access position while the physical resource remains in operation (e.g., remains connected)). That is, by providing a system or means for moving one or more racks in a datacenter during normal operation, access to the lateral sides of the chassis is permitted, which enables larger areas of ingress and egress to be utilized for cable connections. In addition, by moving cable connections to the lateral sides of the chassis, improved thermal cooling flow across the chassis (e.g., front-to-back) is enabled.

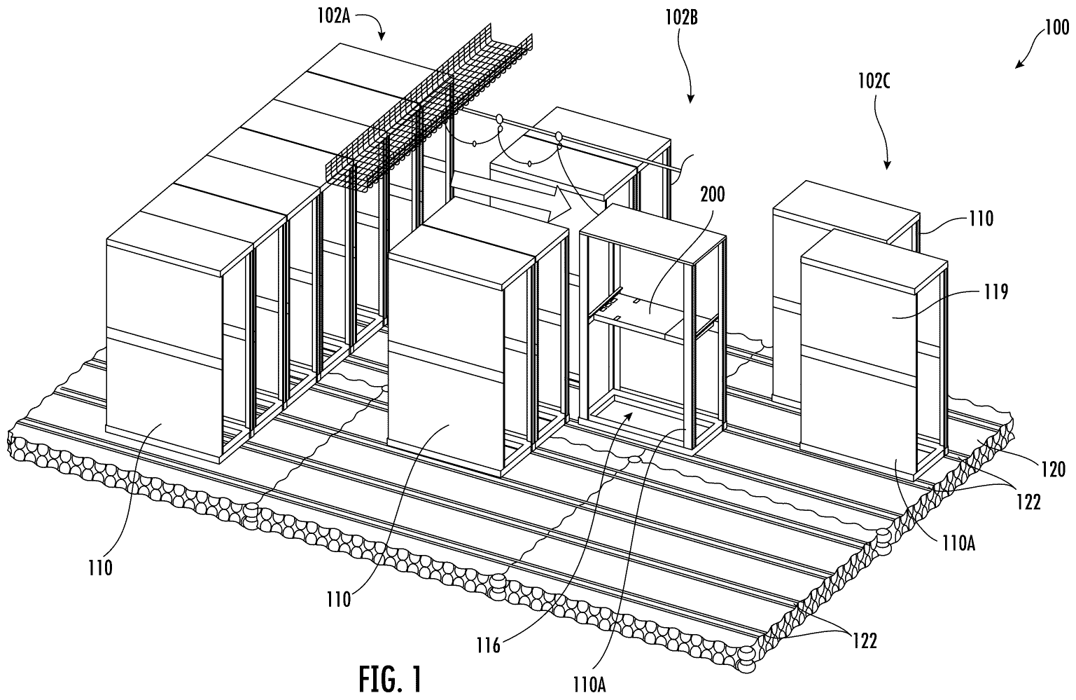

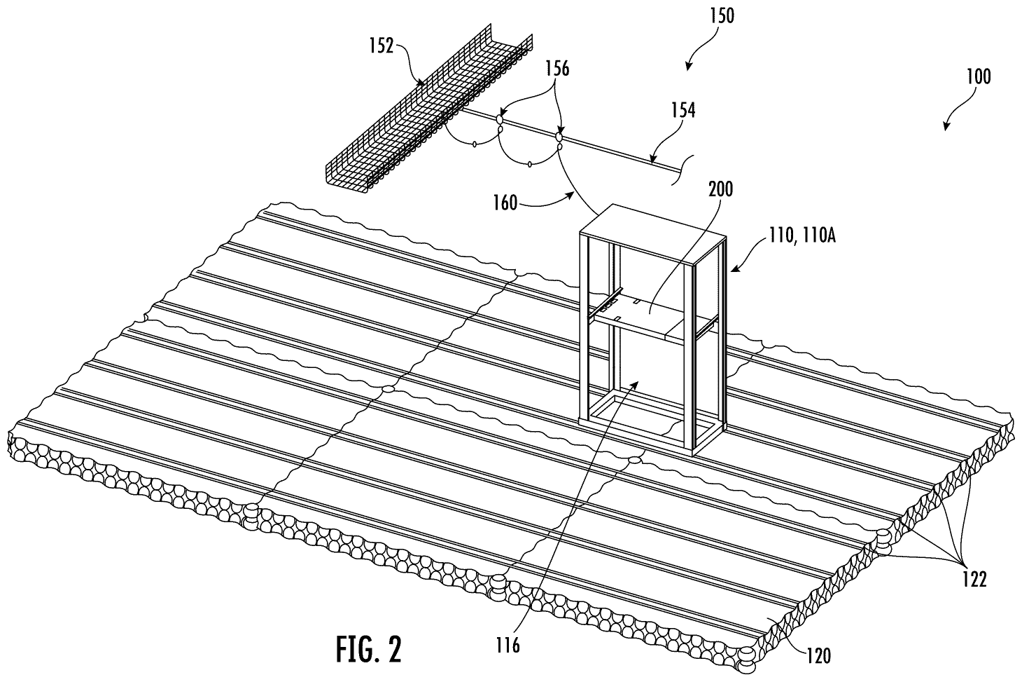

With reference to FIGS. 1 and 2, a schematic representation of a datacenter 100 is illustrated. As generally shown, the datacenter 100 includes first, second and third rows 102A, 102B, 102C of racks 110, with each row 102A, 102B, 102C including a plurality of racks 110. As shown, the first row 102A of racks 110 includes a plurality of individual racks 110 arranged in their first or rest position of operation. The second row of racks 102B includes a rack 110A which has been moved from its first or rest position to a second or access position. Similarly, the third row of racks 102C includes an individual rack 110A in the process of being moved from the first or rest position to the second or access position.

In accordance with one or more features of the present disclosure, the individual racks 110 may be moved from their first or rest position to their second or access position by any suitable motorized and/or automated mechanism or system now known or hereafter developed. In use, in the second or access position, the racks 110 are moved a sufficient distance to enable access to the side panels of the rack 110. In addition, in some embodiments, in the second or access position, the racks 110 are arranged to block airflow to prevent air from bleeding from the hot-aisle to the cold-aisle. That is, in some embodiments, in the second or access position, the motorized and/or automated system may be arranged so that the rack 110 is positioned to stop at a position which slightly overlaps with the adjacent racks, which are positioned in the first or rest position, to provide a seal to prevent hot air from bleeding to the cold-aisle. In addition, in some embodiments, seals such as, for example, brush seals or the like, can be used around the periphery of the racks 110 to further enhance the overall seal.

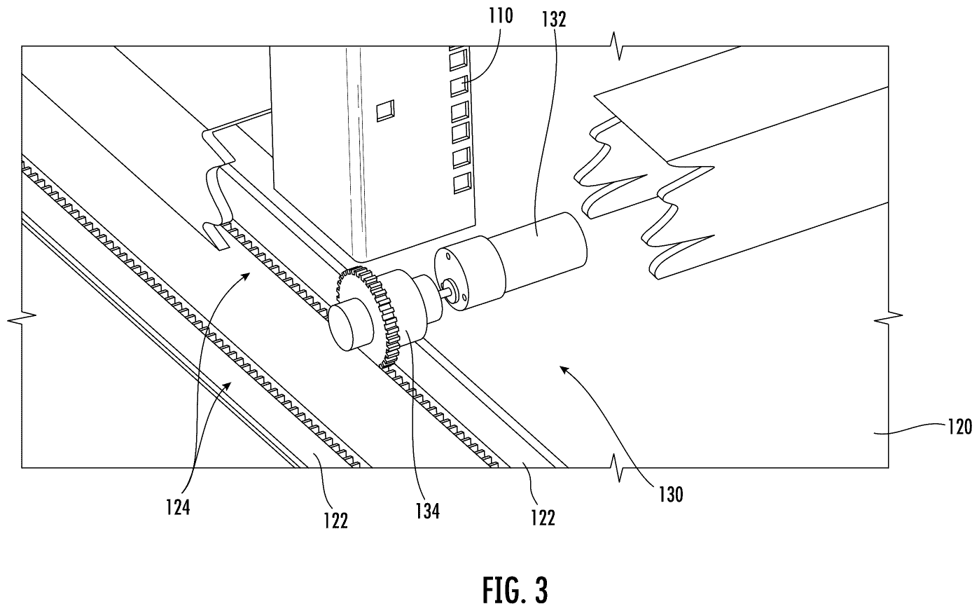

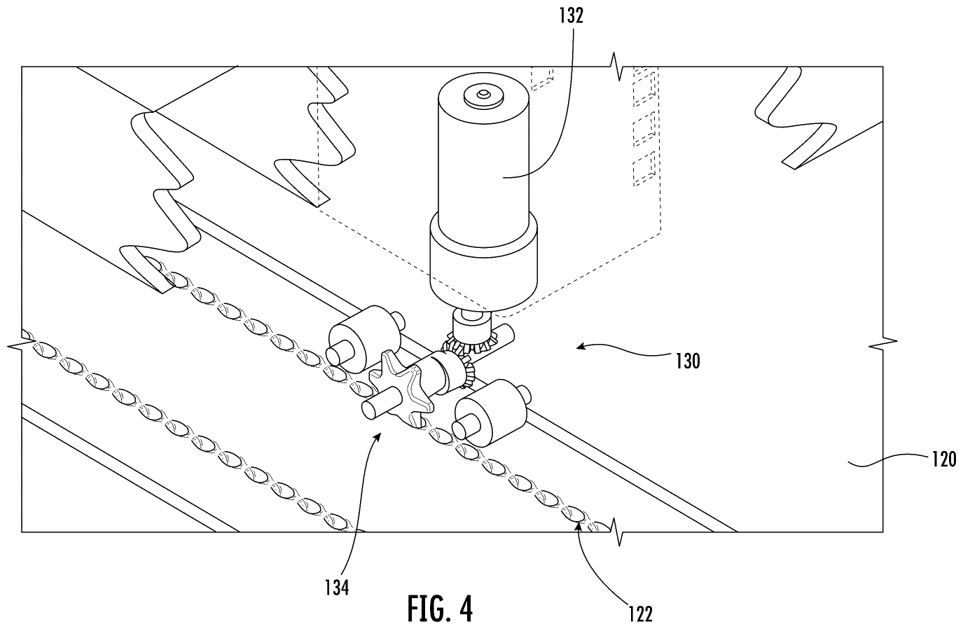

For example, in accordance with one or more features of the present disclosure and with additional reference to FIGS. 3 and 4, the datacenter 100 may include a plurality of floor panels 120 including tracks 122. Each of the racks 110 may include a motorized system such as, for example, a motor and gear system 130 including, for example, a motor 132 and one or more engagement members, shown and described as gears 134, although this is but one configuration and the engagement members may be any suitable structure or mechanism such as, for example, rollers, slides, or the like. In use, activation of the motors 132 causes the gears 134 to interact with the tracks 122 moving the rack 110 from, for example, the first or rest position to the second or access position. In some embodiments, activation of the motors 132, and hence movement of the racks 110, can be achieved via a push button, although this is but one mechanism and any suitable mechanism may be used including, for example, a wireless controller, an APP running on an electronic device, etc. In some embodiments, movement can be controlled via a rack operator panel or server. In some embodiments, movement of the racks 110 can be precisely controlled to position the racks 110, which enables lateral inter-rack connections via automated plugging.

With reference to FIG. 3, in some embodiments, the tracks 122 may include a corresponding gear 124. Thus arranged, the gear track may be integrated into the floor panel 120 as a metal track (e.g., the track system may be coupled to the floor). Alternatively, with reference to FIG. 4, the geared track 122 may be directly integrated into the floor panel 120 (e.g., the track system (i.e., track and/or gears) may be molded into the floor).

In some embodiments, the interconnecting gears 134 between the motor 132 and track 122 may be arranged as a rack and pinion, although this is but one configuration and any suitable gear system may be used to interconnect the motor 132 and track 122. For example, in some embodiments, a rack and pinion gear system may be incorporated into each of the corners of a rack. In use, in some embodiments, activation of the one or more motors rotate the pinions, which moves the racks between the first and second positions. In some embodiments, a single motor may be used to rotate each gear on the rack including, for example, four gears, one in each corner of the rack. Alternatively, each gear may be associated with its own individual motor, or any combination thereof.

The floor panels 120 may be manufactured from any suitable material such as, for example, concrete. In some embodiments, the floor panels 120 may be arranged as prefabricated concrete panels. In use, the prefabricated concrete panels may be interconnected by corresponding joinery between panels. In some embodiments, the prefabricated concrete panels may include honeycombed structure to minimize weight and/or tunnels for post tensioning cables. Thus arranged, associated construction times can be reduced, although it should be appreciated that the floor panels 120 may be manufactured by any suitable means and/or materials now known or hereafter developed. For example, the floor panels 120 can be arranged as poured concrete slabs, metal or composite flooring, etc. As such, the present disclosure should not be limited to any specific type of floor or floor panel unless explicitly claimed.

Alternatively, in some embodiments, tracks 122 may be coupled to existing floors. Thus arranged, existing datacenters can be retrofitted in accordance with one or more features of the present disclosure. Moreover, in some embodiments, the rack 110 may include motorized wheels enabling the racks 110 to be moved between the first or rest position and the second or access position. In addition, thus arranged side-to-side movement of the racks 110 may be provided. Thus arranged, incorporation of motorized wheels facilitates free placement of the racks 110 in forward and back positions, side to side positions, and allow for moving racks 110 to alternate locations if needed.

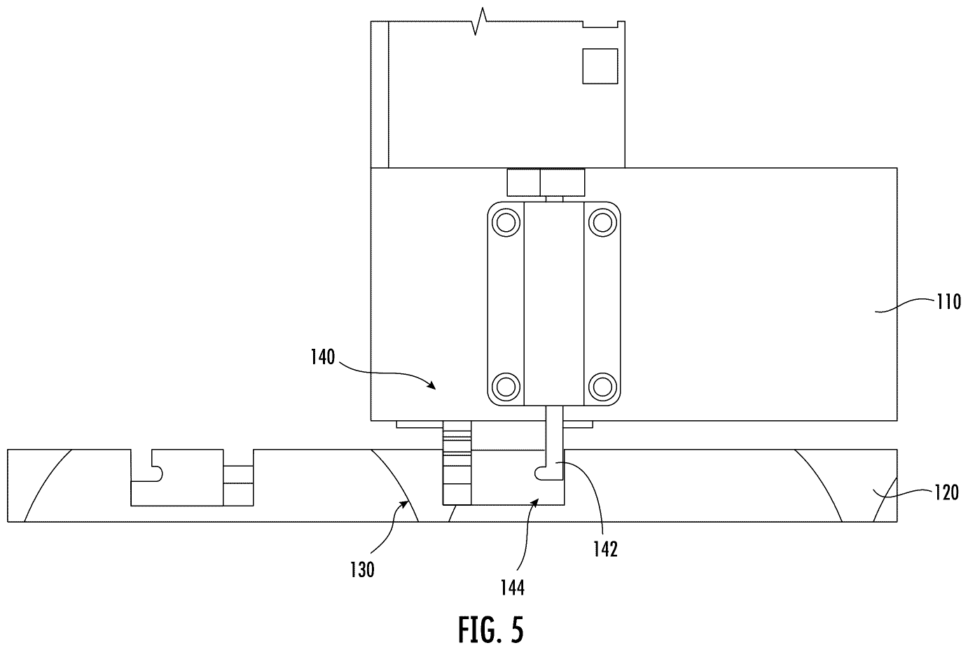

With reference to FIG. 5, in some embodiments, the racks 110 and floor panels 120 may further incorporate an anti-tipping structure 140 to secure the racks 110 in position to avoid tipping of the racks 110 during movement and/or during, for example, an earthquake. In some embodiments, the anti-tipping structure 140 may include a guide 142 extending from a bottom side of the rack 110, the guide 142 arranged to be received with a groove 144 formed in the floor panel 120 to prevent, or at least minimize, the probability that the rack 110 will tip during movement.

With reference to FIG. 2, the datacenters 100 may also include an overhead cable management system 150. For example, the datacenters 100 may include a plurality of overhead cable trays 152, overhead guidewires 154, and pulleys 156, etc. Thus arranged, the multitude of interconnecting rack cables and/or power cables 160 can be run and managed via the overhead cable management system 150. Thus arranged, in use, the racks 110 can move from the first or rest position to the second or access position while remaining connected (e.g., disconnection of the various cables 160 from the chassis 200 positioned within each rack 110 is not required to move the rack 110 from the first position to the second position, this is in contrast to conventional racks, which require the cables to be disconnected before a rack can be moved).

In addition, in some embodiments, the tracks 122 may include a cover to protect the tracks from debris such as, for example, dropped screws or the like. Thus arranged, potential for jamming caused by debris in the tracks is minimized. In use, the covers can be placed manually or automatically with rack movement.

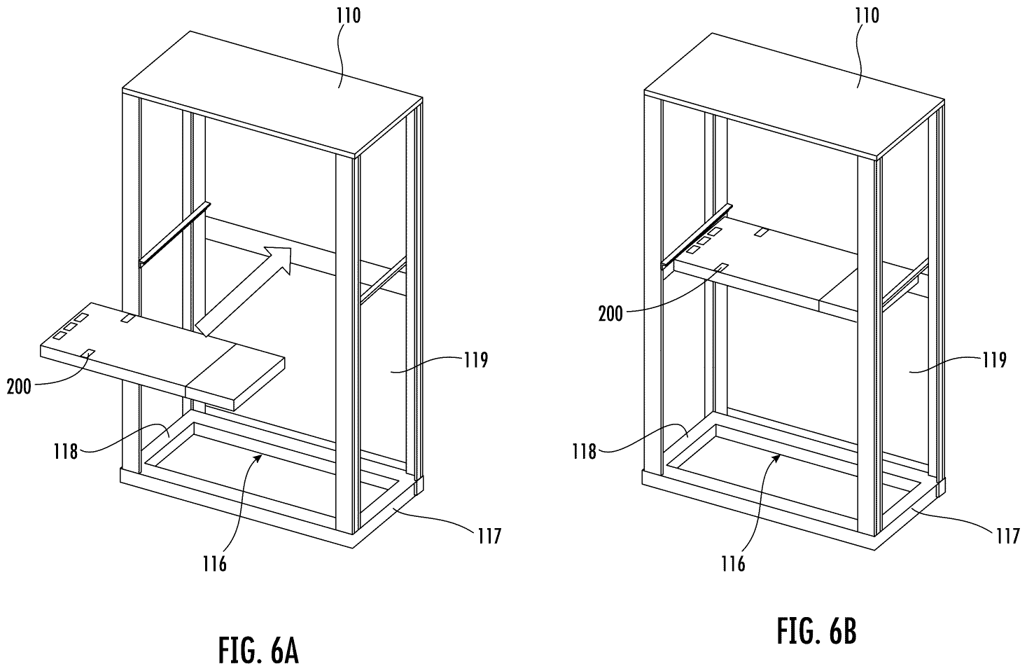

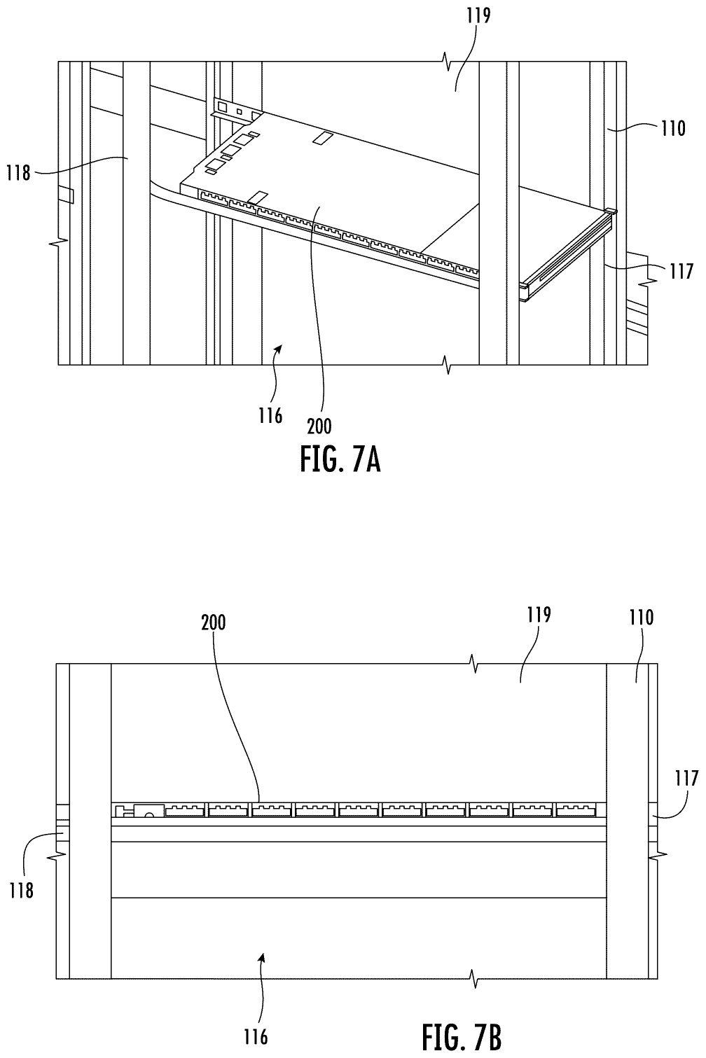

In accordance with one or more features of the present disclosure, which may be used in combination with the motorized and/or automated rack system, or separately therefrom, by moving the racks 110 from the first or rest position to the second or access position, access to the lateral sides 116 of the racks 110, and hence the sides of the chassis 200, is enabled. That is, with reference to FIGS. 6A-7B and as will be readily appreciated, each rack includes a front side 117, a rear side 118 opposite the front side 117, and first and second lateral sides 116 extending between the front and rear sides 117, 118, wherein the front and rear sides 117, 118 have a first length and the first and second lateral sides 116 have a second length, the second length being greater than the first length.

In accordance with one or more features of the present disclosure, with the racks 110 in the second or access position, the chassis 200 may be inserted via a lateral side 116 of the rack 110 as opposed to a front or rear side 117, 118 thereof. Accessing the lateral side 116 of the rack 110 provides increased working space (e.g., maximized open side area). For example, in some embodiments, the lateral sides 116 of the racks 110 may include a panel or door 119 such as, for example, a swing door with multiple latch points at, for example, the corners, to provide enhanced structural integrity during motorized and/or automated movement. Thus arranged, access to the lateral sides 116 of the racks 110 is provided. That is, with the racks 110 in the first or rest position, the first and second lateral sides 116 of the rack 110 are rendered non-accessible due to the racks 110 positioning adjacent to another rack 110. However, when the rack 110 is moved to the second or access position, at least one of the first and second lateral sides 116 (e.g., either first lateral side, the second lateral side, or both) is rendered accessible. As such, each rack 110 may be arranged with one or more slots to receive one or more chassis 200, each chassis 200 including a plurality of I/O connectors 210 to receive a connector of a cable, the plurality of I/O connectors 210 may be arranged along one of the first and second lateral sides 216 of the chassis 200 so that they are accessible when the rack 110 is in the second or access position.

In addition, and/or alternatively, lateral side areas may include EMI treatment. For example, EMI treatment may be positioned on the panels as well as between the chassis to prevent significant EMI emissions from escaping from the racks.

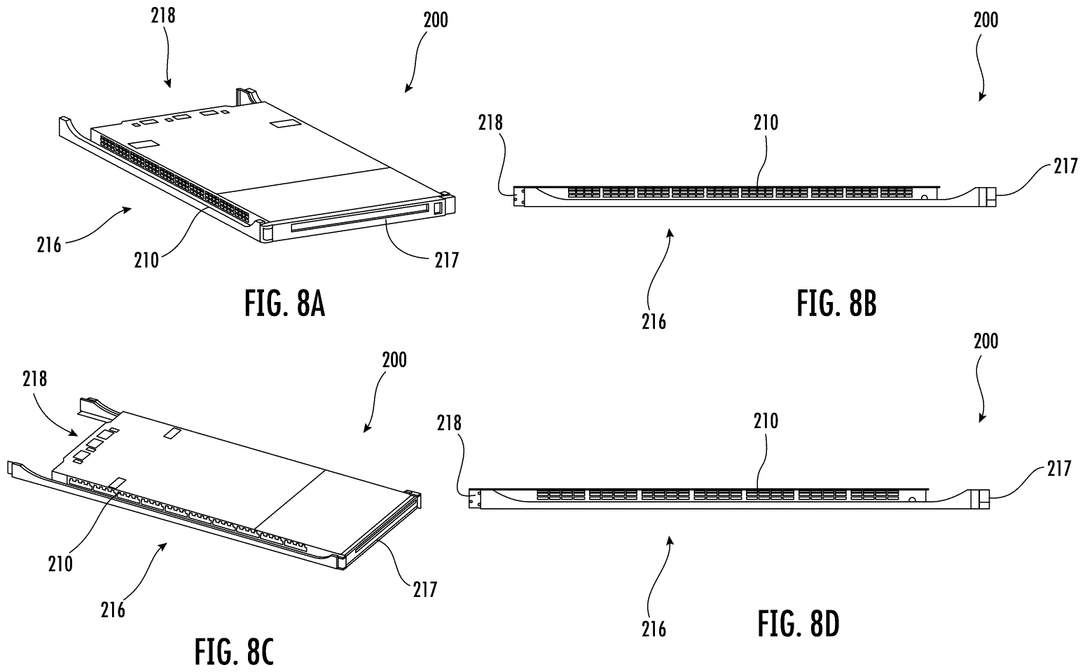

With additional reference to FIGS. 8A-8D, the boards within the chassis, and hence the chassis 200, can be rearranged to enable the I/O connectors 210 to be positioned along the sides 216 of the chassis 200 as opposed to the front and/or back sides 217, 218 of the chassis 200. That is, once a rack 110 is moved to the second or access position, the panel or door 119 can be opened providing access to the lateral sides 116 on the rack 110. Chassis support rails enable maximal egress through the sides of the chassis. By providing increased surface area by moving the I/O connectors 210 in the chassis 200 to the sides as opposed to the front or back sides 217, 218, the larger surface area allows for an increased number of I/O connectors 210. In addition, by facilitating cable connection to the plurality of chassis 200 along the lateral sides 216, increased air flow can be provided front-to-back thereby providing increased thermal cooling (e.g., by moving or running the cables along the lateral sides, the rear of the racks is opened thus providing improved air flow from front (cold-aisle) to back (hot-aisle).

In addition, cable management can be simplified and thus reduce complex congestion of cables caused by rear connector placement. In addition, by providing increased numbers of connectors, a large variety of modules or devices can egress into and out of the chassis sides such as, for example, liquid cooling lines, storage (solid state drives (SSDs)), datacenter-ready secure control modules (DC-SCM modules), etc.). In some embodiments, side access enables the chassis to be slide into and out of the racks as needed. Thus facilitating or providing a number of options for rack architecture such as, for example, alternating conventional front-loaded chassis and side-loaded chassis, enabling chassis to be inserted from either side of a rack, etc. In addition, and/or alternatively, rack-to-rack, side-to-side cabling via cable retraction reels enabling interconnecting cables to run along the sides of the racks (e.g., vertical cabinet space can be provided along the sides of the racks). Moreover, such configurations can enable datacenters to pack tighter rows of racks to achieve higher rack densities. Upon equipment service events, paths through the racks can be created via rackside automation as previously described to provide access to the racks that need servicing, or reconfiguration so that more racks can be installed within a datacenter.

Thus, in accordance with one or more features of the present disclosure, by enabling rackside automation, numerous advantages can be achieved including, for example, increased chassis, rack, and datacenter densities, faster datacenter construction, higher density datacenters, which saves in facilitates costs, improved system cooling, board simplification, which reduces costs, ease of board designs, improved system I/O count (e.g., cable count), improved I/O system to system lengths (e.g., cable lengths), increased HPC rack configuration options, etc.

The various elements of the devices as previously described with reference to the figures include various hardware elements, software elements, or a combination of both. Examples of hardware elements include devices, logic devices, components, processors, microprocessors, circuits, processors, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), memory units, logic gates, registers, semiconductor device, chips, microchips, chip sets, and so forth. Examples of software elements include software components, programs, applications, computer programs, application programs, system programs, software development programs, machine programs, operating system software, middleware, firmware, software modules, routines, subroutines, functions, methods, procedures, software interfaces, application program interfaces (API), instruction sets, computing code, computer code, code segments, computer code segments, words, values, symbols, or any combination thereof. However, determining whether an embodiment is implemented using hardware elements and/or software elements varies in accordance with any number of factors, such as desired computational rate, power levels, heat tolerances, processing cycle budget, input data rates, output data rates, memory resources, data bus speeds and other design or performance constraints, as desired for a given implementation.

One or more aspects of at least one embodiment are implemented by representative instructions stored on a machine-readable medium which represents various logic within the processor, which when read by a machine causes the machine to fabricate logic to perform the techniques described herein. Such representations, known as “intellectual property (IP) cores” are stored on a tangible, machine readable medium and supplied to various customers or manufacturing facilities to load into the fabrication machines that make the logic or processor. Some embodiments are implemented, for example, using a machine-readable medium or article which may store an instruction or a set of instructions that, when executed by a machine, causes the machine to perform a method and/or operations in accordance with the embodiments. Such a machine includes, for example, any suitable processing platform, computing platform, computing device, processing device, computing system, processing system, processing devices, computer, processor, or the like, and is implemented using any suitable combination of hardware and/or software. The machine-readable medium or article includes, for example, any suitable type of memory unit, memory device, memory article, memory medium, storage device, storage article, storage medium and/or storage unit, for example, memory, removable or non-removable media, erasable or non-erasable media, writeable or re-writeable media, digital or analog media, hard disk, floppy disk, Compact Disk Read Only Memory (CD-ROM), Compact Disk Recordable (CD-R), Compact Disk Rewriteable (CD-RW), optical disk, magnetic media, magneto-optical media, removable memory cards or disks, various types of Digital Versatile Disk (DVD), a tape, a cassette, or the like. The instructions include any suitable type of code, such as source code, compiled code, interpreted code, executable code, static code, dynamic code, encrypted code, and the like, implemented using any suitable high-level, low-level, object-oriented, visual, compiled and/or interpreted programming language.

As utilized herein, terms “component,” “system,” “interface,” and the like are intended to refer to a computer-related entity, hardware, software (e.g., in execution), and/or firmware. For example, a component is a processor (e.g., a microprocessor, a controller, or other processing device), a process running on a processor, a controller, an object, an executable, a program, a storage device, a computer, a tablet PC and/or a user equipment (e.g., mobile phone, etc.) with a processing device. By way of illustration, an application running on a server and the server is also a component. One or more components reside within a process, and a component is localized on one computer and/or distributed between two or more computers. A set of elements or a set of other components are described herein, in which the term “set” can be interpreted as “one or more.”

Further, these components execute from various computer readable storage media having various data structures stored thereon such as with a module, for example. The components communicate via local and/or remote processes such as in accordance with a signal having one or more data packets (e.g., data from one component interacting with another component in a local system, distributed system, and/or across a network, such as, the Internet, a local area network, a wide area network, or similar network with other systems via the signal).

As another example, a component is an apparatus with specific functionality provided by mechanical parts operated by electric or electronic circuitry, in which the electric or electronic circuitry is operated by a software application or a firmware application executed by one or more processors. The one or more processors are internal or external to the apparatus and execute at least a part of the software or firmware application. As yet another example, a component is an apparatus that provides specific functionality through electronic components without mechanical parts; the electronic components include one or more processors therein to execute software and/or firmware that confer(s), at least in part, the functionality of the electronic components.

Use of the word exemplary is intended to present concepts in a concrete fashion. As used in this application, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form. Furthermore, to the extent that the terms “including,” “includes,” “having,” “has,” “with,” or variants thereof are used in either the detailed description or the claims, such terms are intended to be inclusive in a manner similar to the term “comprising.” Additionally, in situations wherein one or more numbered items are discussed (e.g., a “first X,” a “second X,” etc.), in general the one or more numbered items may be distinct or they may be the same, although in some situations the context may indicate that they are distinct or that they are the same.

As used herein, the term “circuitry” may refer to, be part of, or include a circuit, an integrated circuit (IC), a monolithic IC, a discrete circuit, a hybrid integrated circuit (HIC), an Application Specific Integrated Circuit (ASIC), an electronic circuit, a logic circuit, a microcircuit, a hybrid circuit, a microchip, a chip, a chiplet, a chipset, a multi-chip module (MCM), a semiconductor die, a system on a chip (SoC), a processor (shared, dedicated, or group), a processor circuit, a processing circuit, or associated memory (shared, dedicated, or group) operably coupled to the circuitry that execute one or more software or firmware programs, a combinational logic circuit, or other suitable hardware components that provide the described functionality. In some embodiments, the circuitry is implemented in, or functions associated with the circuitry are implemented by, one or more software or firmware modules. In some embodiments, circuitry includes logic, at least partially operable in hardware. It is noted that hardware, firmware and/or software elements may be collectively or individually referred to herein as “logic” or “circuit.”

Some embodiments are described using the expression “one embodiment” or “an embodiment” along with their derivatives. These terms mean that a particular feature, structure, or characteristic described in connection with the embodiment is included in at least one embodiment. The appearances of the phrase “in one embodiment” in various places in the specification are not necessarily all referring to the same embodiment. Moreover, unless otherwise noted the features described above are recognized to be usable together in any combination. Thus, any features discussed separately can be employed in combination with each other unless it is noted that the features are incompatible with each other.

Some embodiments are presented in terms of program procedures executed on a computer or network of computers. A procedure is here, and generally, conceived to be a self-consistent sequence of operations leading to a desired result. These operations are those requiring physical manipulations of physical quantities. Usually, though not necessarily, these quantities take the form of electrical, magnetic or optical signals capable of being stored, transferred, combined, compared, and otherwise manipulated. It proves convenient at times, principally for reasons of common usage, to refer to these signals as bits, values, elements, symbols, characters, terms, numbers, or the like. It should be noted, however, that all of these and similar terms are to be associated with the appropriate physical quantities and are merely convenient labels applied to those quantities.

Further, the manipulations performed are often referred to in terms, such as adding or comparing, which are commonly associated with mental operations performed by a human operator. No such capability of a human operator is necessary, or desirable in most cases, in any of the operations described herein, which form part of one or more embodiments. Rather, the operations are machine operations. Useful machines for performing operations of various embodiments include general purpose digital computers or similar devices.

Some embodiments are described using the expression “coupled” and “connected” along with their derivatives. These terms are not necessarily intended as synonyms for each other. For example, some embodiments are described using the terms “connected” and/or “coupled” to indicate that two or more elements are in direct physical or electrical contact with each other. The term “coupled,” however, also means that two or more elements are not in direct contact with each other, but yet still co-operate or interact with each other.

Various embodiments also relate to apparatus or systems for performing these operations. This apparatus is specially constructed for the required purpose or it comprises a general-purpose computer as selectively activated or reconfigured by a computer program stored in the computer. The procedures presented herein are not inherently related to a particular computer or other apparatus. Various general-purpose machines are used with programs written in accordance with the teachings herein, or it proves convenient to construct more specialized apparatus to perform the required method steps. The required structure for a variety of these machines are apparent from the description given.

It is emphasized that the Abstract of the Disclosure is provided to allow a reader to quickly ascertain the nature of the technical disclosure. It is submitted with the understanding that it will not be used to interpret or limit the scope or meaning of the claims. In addition, the following claims are hereby incorporated into the Detailed Description, with each claim standing on its own as a separate embodiment. In the appended claims, the terms “including” and “in which” are used as the plain-English equivalents of the respective terms “comprising” and “wherein,” respectively. Moreover, the terms “first,” “second,” “third,” and so forth, are used merely as labels, and are not intended to impose numerical requirements on their objects.

The following examples pertain to further embodiments, from which numerous permutations and configurations will be apparent.

Example 1. An apparatus, comprising: a rack comprising a motorized system, the motorized system comprising at least one motor, a first engagement member, and a second engagement member, the first engagement member being operatively associated with a motor of the at least one motor, the second engagement member being operatively associated with a motor of the at least one motor, the at least one motor operable to move the first engagement member and the second engagement member to move the rack between a first position and a second position.

Example 2. The apparatus of example 1, wherein the first and second engagement members are selected from one or a gear, rollers, and a slide.

Example 3. The apparatus of example 1, wherein the rack includes a front side, a rear side opposite the front side, and first and second lateral sides extending between the front and rear sides, wherein the front and rear sides have a first length and the first and second lateral sides have a second length, the second length being greater than the first length, wherein at least one of the first or second lateral side is non-accessible when the rack is in the first position, and the at least one of the first or second lateral side is rendered accessible when the rack is in the second position.

Example 4. The apparatus of example 3, wherein the rack comprises a slot to receive a chassis comprising a plurality of input/output (I/O) connectors to receive a connector of a cable, wherein the plurality of I/O connectors are arranged along one of the first and second lateral sides of the chassis so that they are accessible when the rack is in the second position.

Example 5. The apparatus of example 1, wherein the at least one motor is activated via a push button, a wireless controller, or an application (APP) running on an electronic device.

Example 6. A system, comprising: a floor comprising a plurality of tracks; and a first rack comprising a motorized system for interacting with the plurality of tracks, the motorized system comprising at least one motor, a first engagement member, and a second engagement member, the first engagement member being operatively associated with a motor of the at least one motor and to a first track of the plurality of tracks and the second engagement member being operatively associated with a motor of the at least one motor and to a second track of the plurality of tracks, the at least one motor being operable to move the first engagement member and the second engagement member along the first track and the second track, respectively, between a first position and a second position.

Example 7. The system of example 6, wherein the first and second engagement members are selected from one or a gear, rollers, and a slide.

Example 8. The system of example 6, wherein the rack includes a front side, a rear side opposite the front side, and first and second lateral sides extending between the front and rear sides, wherein the front and rear sides have a first length and the first and second lateral sides have a second length, the second length being greater than the first length, wherein at least one of the first or second lateral side is non-accessible when the rack is in the first position, and the at least one of the first or second lateral side is rendered accessible when the rack is in the second position.

Example 9. The system of example 8, wherein the first rack comprises a slot to receive a chassis comprising a plurality of I/O connectors to receive a connector of a cable, wherein the plurality of I/O connectors are arranged along one of the first and second lateral sides of the chassis so that they are accessible when the rack is in the second position.

Example 10. The system of example 8, further comprising a second rack positioned adjacent to one of the first and second lateral sides of the first rack when the first rack is in the first position.

Example 11. The of system of example 6, wherein the at least one motor is activated via a push button, a wireless controller, or an APP running on an electronic device.

Example 12. The system of example 6, wherein the first and second engagement members are gears, and the plurality of tracks include a corresponding gear to interact with the gears on the first rack.

Example 13. The system of example 6, wherein the floor comprises a plurality of prefabricated floor panels.

Example 14. The system of example 6, wherein the first rack further comprises an anti-tipping structure to secure the first rack to avoid tipping during movement.

Example 15. The system of example 14, wherein the anti-tipping structure includes a guide extending from a bottom side of the first rack, the guide arranged to be received with a groove formed in the floor.

Example 16. The system of example 6, further comprising an overhead cable management system to manage a plurality of cables running to and from the first rack.

Example 17. The system of example 16, wherein the overhead cable management system includes a plurality of overhead cable trays, overhead guidewires, and pulleys.

Example 18. A system, comprising: a floor comprising a plurality of tracks; a first rack comprising a motorized system for interacting with the plurality of tracks, the motorized system comprising at least one motor, a first engagement member, and a second engagement member, the first engagement member being operatively associated with a motor of the at least one motor and to a first track of the plurality of tracks and the second engagement member being operatively associated with a motor of the at least one motor and to a second track of the plurality of tracks, the at least one motor being operable to move the first engagement member and the second engagement member along the first track and the second track, respectively, between a first position and a second position; a second rack comprising a motorized system for interacting with the plurality of tracks, the motorized system comprising at least one motor, a third engagement member, and a fourth engagement member, the third engagement member being operatively associated with a motor of the at least one motor and to a third track of the plurality of tracks and the fourth engagement member being operatively associated with a motor of the at least one motor and to a fourth track of the plurality of tracks, the at least one motor being operable to move the third engagement member and the fourth engagement member along the third track and the fourth track, respectively, between a first position and a second position; wherein in the first position, the first rack and the second rack are positioned in a side-by-side configuration; and in the second position, one of the first and second racks is moved relative to the other one of the first and second racks.

Example 19. The system of example 18, wherein each of the first and second racks includes a front side, a rear side opposite the front side, and first and second lateral sides extending between the front and rear sides, wherein the front and rear sides have a first length and the first and second lateral sides have a second length, the second length being greater than the first length, wherein at least one of the first or second lateral side is non-accessible when the first and second racks are in the first position, respectively, and the at least one of the first or second lateral side is rendered accessible when the first and second rack is in the second position, respectively.

Example 20. The system of example 18, wherein each of the first and second racks comprise a slot to receive a chassis comprising a plurality of I/O connectors to receive a connector of a cable, wherein the plurality of I/O connectors are arranged along one of the first and second lateral sides of the chassis so that they are accessible when the first and second racks are in the second position, respectively.

Example 21. The system of example 18, wherein the first, second, third, and fourth engagement members are gears, and the plurality of tracks each comprise a corresponding gear to interact with the gears on the first and second racks.

Example 22. A system comprising a plurality of tracks coupled to or integrated with a floor; and a plurality of racks arranged in a side-by-side fashion in one or more rows, at least one of the racks include a motorized system for interacting with at least one of the plurality of tracks, the rack moveable between a first position and a second position; wherein in the first position, the rack is arranged in the side-by-side fashion with adjacent racks, and in the second position, the rack is moved so that a lateral side of the rack is accessible; and wherein the racks are moveable from the first position to the second position while remaining in normal operation.

Example 23. The system of example 22, wherein the motorized system comprises a motor and one or more gears for interacting with the at least one of the plurality of tracks; and upon activation of the motor, the one or more gears are rotated to move the rack.

Example 24. A system, comprising a plurality of tracks coupled to or integrated with a floor of the datacenter; and a plurality of racks arranged in a side-by-side fashion in one or more rows, the racks including a motorized system for interacting with at least one of the plurality of tracks, the racks moveable between a first position and a second position; wherein: each of the plurality of racks include a plurality of chassis, at least some of the plurality of chassis including a plurality of I/O connectors to receive a connector of a cable, the plurality of I/O connectors are arranged along a lateral side of the chassis; in the first position, the rack is arranged in the side-by-side fashion with adjacent racks; in the second position, the rack is positioned so that a lateral side of the rack is accessible to provide access to the I/O connectors formed in the lateral side of the chassis; and the racks are moveable from the first position to the second position while remaining in normal operation.

Example 25. The system of example 24, wherein the motorized system comprises a motor and one or more gears for interacting with the at least one of the plurality of tracks; and upon activation of the motor, the one or more gears are rotated to move the rack.

Example 26. An apparatus comprising a plurality of racks arranged in a side-by-side fashion in one or more rows, at least one of the racks including a motorized system for moving the rack between a first position and a second position; wherein in the first position, the rack is arranged in the side-by-side fashion with adjacent racks, and in the second position, the rack is moved so that a lateral side of the rack is accessible.

What is claimed is:

1. An apparatus, comprising:
a rack comprising a motorized system, the motorized system comprising at least one motor, a first engagement member, and a second engagement member, the first engagement member being operatively associated with a motor of the at least one motor, the second engagement member being operatively associated with a motor of the at least one motor, the at least one motor operable to move the first engagement member and the second engagement member to move the rack between a first position and a second position.

2. The apparatus of claim 1, wherein the first and second engagement members are selected from one or a gear, rollers, and a slide.

3. The apparatus of claim 1, wherein the rack includes a front side, a rear side opposite the front side, and first and second lateral sides extending between the front and rear sides, wherein the front and rear sides have a first length and the first and second lateral sides have a second length, the second length being greater than the first length,
wherein at least one of the first or second lateral side is non-accessible when the rack is in the first position, and the at least one of the first or second lateral side is rendered accessible when the rack is in the second position.

4. The apparatus of claim 3, wherein the rack comprises a slot to receive a chassis comprising a plurality of input/output (I/O) connectors to receive a connector of a cable, wherein the plurality of I/O connectors are arranged along one of the first and second lateral sides of the chassis so that they are accessible when the rack is in the second position.

5. The apparatus of claim 1, wherein the at least one motor is activated via a push button, a wireless controller, or an application (APP) running on an electronic device.

6. A system, comprising:
a floor comprising a plurality of tracks; and
a first rack comprising a motorized system for interacting with the plurality of tracks, the motorized system comprising at least one motor, a first engagement member, and a second engagement member, the first engagement member being operatively associated with a motor of the at least one motor and to a first track of the plurality of tracks and the second engagement member being operatively associated with a motor of the at least one motor and to a second track of the plurality of tracks, the at least one motor being operable to move the first engagement member and the second engagement member along the first track and the second track, respectively, between a first position and a second position.

7. The system of claim 6, wherein the first and second engagement members are selected from one or a gear, rollers, and a slide.

8. The system of claim 6, wherein the rack includes a front side, a rear side opposite the front side, and first and second lateral sides extending between the front and rear sides, wherein the front and rear sides have a first length and the first and second lateral sides have a second length, the second length being greater than the first length,
wherein at least one of the first or second lateral side is non-accessible when the rack is in the first position, and the at least one of the first or second lateral side is rendered accessible when the rack is in the second position.

9. The system of claim 8, wherein the first rack comprises a slot to receive a chassis comprising a plurality of I/O connectors to receive a connector of a cable, wherein the plurality of I/O connectors are arranged along one of the first and second lateral sides of the chassis so that they are accessible when the rack is in the second position.

10. The system of claim 8, further comprising a second rack positioned adjacent to one of the first and second lateral sides of the first rack when the first rack is in the first position.

11. The of system of claim 6, wherein the at least one motor is activated via a push button, a wireless controller, or an APP running on an electronic device.

12. The system of claim 6, wherein the first and second engagement members are gears, and the plurality of tracks include a corresponding gear to interact with the gears on the first rack.

13. The system of claim 6, wherein the floor comprises a plurality of prefabricated floor panels.

14. The system of claim 6, wherein the first rack further comprises an anti-tipping structure to secure the first rack to avoid tipping during movement;
wherein the anti-tipping structure includes a guide extending from a bottom side of the first rack, the guide arranged to be received with a groove formed in the floor.

15. The system of claim 6, further comprising an overhead cable management system to manage a plurality of cables running to and from the first rack.

16. The system of claim 15, wherein the overhead cable management system includes a plurality of overhead cable trays, overhead guidewires, and pulleys.

17. A system, comprising:
a floor comprising a plurality of tracks;
a first rack comprising a motorized system for interacting with the plurality of tracks, the motorized system comprising at least one motor, a first engagement member, and a second engagement member, the first engagement member being operatively associated with a motor of the at least one motor and to a first track of the plurality of tracks and the second engagement member being operatively associated with a motor of the at least one motor and to a second track of the plurality of tracks, the at least one motor being operable to move the first engagement member and the second engagement member along the first track and the second track, respectively, between a first position and a second position;
a second rack comprising a motorized system for interacting with the plurality of tracks, the motorized system comprising at least one motor, a third engagement member, and a fourth engagement member, the third engagement member being operatively associated with a motor of the at least one motor and to a third track of the plurality of tracks and the fourth engagement member being operatively associated with a motor of the at least one motor and to a fourth track of the plurality of tracks, the at least one motor being operable to move the third engagement member and the fourth engagement member along the third track and the fourth track, respectively, between a first position and a second position;
wherein in the first position, the first rack and the second rack are positioned in a side-by-side configuration; and in the second position, one of the first and second racks is moved relative to the other one of the first and second racks.

18. The system of claim 17, wherein each of the first and second racks includes a front side, a rear side opposite the front side, and first and second lateral sides extending between the front and rear sides, wherein the front and rear sides have a first length and the first and second lateral sides have a second length, the second length being greater than the first length,
wherein at least one of the first or second lateral side is non-accessible when the first and second racks are in the first position, respectively, and the at least one of the first or second lateral side is rendered accessible when the first and second rack is in the second position, respectively.

19. The system of claim 18, wherein each of the first and second racks comprise a slot to receive a chassis comprising a plurality of I/O connectors to receive a connector of a cable, wherein the plurality of I/O connectors are arranged along one of the first and second lateral sides of the chassis so that they are accessible when the first and second racks are in the second position, respectively.

20. The system of claim 18, wherein the first, second, third, and fourth engagement members are gears, and the plurality of tracks each comprise a corresponding gear to interact with the gears on the first and second racks.
